(19) United States
(12) Patent Application Publication
(10) Pub. No.: US 2026/0075834 A1
(43) Pub. Date: Mar. 12, 2026

(54) FERROELECTRIC STRUCTURE, AND SEMICONDUCTOR DEVICE AND MEMORY DEVICE BOTH USING THE SAME

(71) Applicants: Samsung Electronics Co., Ltd., Suwon-si (KR); THE CHANCELLOR, MASTERS AND SCHOLARS OF THE UNIVERSITY OF CAMBRIDGE, Cambridge (GB)

(72) Inventors: Dukhyun CHOE, Suwon-si (KR); Judith DRISCOLL, Cambridge (GB); Ji Soo KIM, Cambridge (GB)

(73) Assignees: Samsung Electronics Co., Ltd., Suwon-si (KR); THE CHANCELLOR, MASTERS AND SCHOLARS OF THE UNIVERSITY OF CAMBRIDGE, Cambridge (GB)

(21) Appl. No.: 19/323,027

(22) Filed: Sep. 9, 2025

(30) Foreign Application Priority Data
Sep. 10, 2024 (KR) 10-2024-0123406

(51) Int. Cl. H10B 51/30; H10B 51/20

(52) U.S. Cl. CPC H10B 51/30; H10B 51/20

(57) ABSTRACT

Provided are a ferroelectric structure, and a semiconductor device and a memory device both using the ferroelectric structure. The ferroelectric structure includes a substrate, a ferroelectric layer on the substrate and including a hafnium oxide-based ferroelectric having a rhombohedral phase and doped with samarium (Sm), and an electrode on the ferroelectric layer.

### CROSS-REFERENCE TO RELATED APPLICATION

This application claims the benefit of Korean Patent Application No. 10-2024-0123406, filed on Sep. 10, 2024, in the Korean Intellectual Property Office, but the disclosure of which is incorporated herein in its entirety by reference.

### BACKGROUND

### 1. Field

The disclosure relates to ferroelectric structures, and semiconductor devices and memory devices both using the ferroelectric structure.

### 2. Description of the Related Art

Ferroelectrics are materials that have ferroelectricity, which maintain spontaneous polarization by aligning the internal dipole moment even when no electric field is applied from the outside. Research has been conducted to apply semiconductor devices containing ferroelectrics to memory devices. For example, ferroelectric field-effect transistors are semiconductor devices that implement memory characteristics by controlling a threshold voltage according to the polarization direction of a ferroelectric material by using a ferroelectric material as a gate insulating film. The ferroelectric field-effect transistors have advantages such as a lower operating voltage, a faster programming speed, etc.

### SUMMARY

Some example embodiments provide ferroelectric structures, and semiconductor devices and memory devices both using the ferroelectric structure.

Additional aspects will be set forth in part in the description which follows and, in part, will be apparent from the description, or may be learned by practice of the presented example embodiments.

According to an example embodiment of the disclosure, a ferroelectric structure includes a substrate, a ferroelectric layer on the substrate, the ferroelectric layer including a hafnium oxide-based ferroelectric having a rhombohedral phase and doped with samarium (Sm), and an electrode on the ferroelectric layer.

The content of the rhombohedral phase in the ferroelectric layer may be 30% to 80%.

Sm may be doped in an entire area of the ferroelectric layer.

The content of Sm in the ferroelectric layer may be 1 at % to 5 at %.

The ferroelectric layer may include a first region and a second region, the first region including a hafnium oxide-based ferroelectric doped with Sm, the second region including a hafnium oxide-based ferroelectric undoped with Sm.

The hafnium oxide-based ferroelectric may further include at least one of Zr, La, Al, Si, or Y.

The ferroelectric structure may further include at least one interface layer inside the ferroelectric layer.

The substrate may include a semiconductor material.

The substrate may include a conductive material.

According to an example embodiment of the disclosure, a semiconductor device includes a channel layer including a semiconductor material, a ferroelectric layer on the channel layer, the ferroelectric layer including a hafnium oxide-based ferroelectric having a rhombohedral phase and doped with samarium (Sm), and a gate electrode on the ferroelectric layer.

Sm may be doped in an entire area of the ferroelectric layer.

The ferroelectric layer may include a first region and a second region, the first region including a hafnium oxide-based ferroelectric doped with Sm, the second region including a hafnium oxide-based ferroelectric undoped with Sm.

The hafnium oxide-based ferroelectric may further include at least one of Zr, La, Al, Si, or Y.

The semiconductor device may further include at least one interface layer inside the ferroelectric layer.

According to an example embodiment of the disclosure, a memory device includes a plurality of memory cells arranged perpendicular to a substrate, wherein each of the plurality of memory cells may include a channel layer, a ferroelectric layer on the channel layer, the ferroelectric layer including a hafnium oxide-based ferroelectric having a rhombohedral phase and doped with samarium (Sm), and a gate electrode on the ferroelectric layer.

The channel layer may extend perpendicularly to the substrate.

The gate electrode may extend perpendicularly to the substrate.

Sm may be doped in an entire area of the ferroelectric layer.

The ferroelectric layer may include a first region and a second region, the first region including a hafnium oxide-based ferroelectric doped with Sm, the second region including a hafnium oxide-based ferroelectric undoped with Sm.

The hafnium oxide-based ferroelectric may further include at least one of Zr, La, Al, Si, or Y.

### BRIEF DESCRIPTION OF THE DRAWINGS

These and/or other aspects will become apparent and more readily appreciated from the following description, of some example embodiments, taken in conjunction with the accompanying drawings in which:

FIG. 1 is a schematic cross-sectional view of a ferroelectric structure according to an example embodiment;

FIG. 2 is a schematic cross-sectional view of a ferroelectric structure according to another example embodiment;

FIGS. 3A to 3C illustrate a ferroelectric structure according to a comparative example, a ferroelectric structure according to one example embodiment (e.g., the example embodiment of FIG. 1), and a ferroelectric structure according to another example embodiment (e.g., the example embodiment of FIG. 2), respectively;

FIG. 4A is a graph showing results of measuring current characteristics and polarization characteristics of an “HZO” ferroelectric according to the comparative example illustrated in FIG. 3A;

FIG. 4B is a graph showing results of measuring current characteristics and polarization characteristics of the “HZSO” ferroelectric according to the example embodiment illustrated in FIG. 3B;

FIG. 4C is a graph showing results of measuring current characteristics and polarization characteristics of the “HZO/HZSO” ferroelectric according to the example embodiment illustrated in FIG. 3C;

FIG. 5 is a graph showing a comparison of a coercive field with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C;

FIG. 6 is a graph showing a comparison of the coercive field Ec and remnant polarization Pr with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C;

FIG. 7A is a graph showing an X-ray diffraction (XRD) analysis result (a diffraction peak according to a 2θ-ω change) with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C;

FIG. 7B is a graph showing an X-ray rocking curve (a diffraction peak according to a ω change) with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C;

FIG. 7C is a graph showing quantification of a ratio of a “B” peak to an “S” peak, from the result illustrated in FIG. 7B, with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C;

FIG. 8 is a schematic cross-sectional view of a ferroelectric structure according to another example embodiment;

FIG. 9 is a schematic cross-sectional view of a ferroelectric structure according to another example embodiment;

FIG. 10 is a schematic cross-sectional view of a semiconductor device according to an example embodiment;

FIG. 11 is a schematic cross-sectional view of a semiconductor device according to another example embodiment.

FIG. 12 is a schematic cross-sectional view of a semiconductor device according to another example embodiment;

FIG. 13 is a schematic cross-sectional view of a semiconductor device according to another example embodiment;

FIG. 14 is a schematic cross-sectional view of a semiconductor device according to another example embodiment;

FIG. 15 is a schematic cross-sectional view of a semiconductor device according to another example embodiment;

FIGS. 16 and 17 are views schematically illustrating a semiconductor device according to another example embodiment;

FIG. 18 is a view schematically illustrating a semiconductor device according to another example embodiment;

FIGS. 19 and 20 are views illustrating a memory device according to an example embodiment;

FIGS. 21 to 23 are views illustrating a memory device according to another example embodiment;

FIG. 24 is a conceptual view schematically showing device architecture applicable to an example electronic device;

FIG. 25 is a block diagram of a memory system according to an example embodiment; and

FIG. 26 is a block diagram of a neuromorphic apparatus according to an example embodiment and an external device connected thereto.

### DETAILED DESCRIPTION

Reference will now be made in detail to example embodiments, examples of which are illustrated in the accompanying drawings, wherein like reference numerals refer to like elements throughout. In this regard, the disclosed example embodiments may have different forms and should not be construed as being limited to the descriptions set forth herein. Accordingly, the disclosed example embodiments are merely described below, by referring to the figures, to explain aspects. As used herein, the term “and/or” includes any and all combinations of one or more of the associated listed items. Expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Hereinafter, some example embodiments are described below in detail with reference to the accompanying drawings. Sizes of each constituent element in the drawings may be exaggerated for convenience of explanation and clarity. The example embodiments described below are examples, and other modifications may be produced from the embodiments.

When a constituent element is disposed “above” or “on” to another constituent element, the constituent element may be only directly on the other constituent element or above the other constituent elements in a non-contact manner. As used herein, the singular forms “a,” “an” and “the” are intended to include the plural forms as well, unless the context clearly indicates otherwise. It will be further understood that the terms “comprises” and/or “comprising” used herein specify the presence of stated features or elements, but do not preclude the presence or addition of one or more other features or elements.

The use of the terms “a,” “an,” “the,” and similar referents in the context of describing the disclosure (especially in the context of the following claims) is to be construed to cover both the singular and the plural. Also, the operations of all methods described herein can be performed in any suitable order unless otherwise indicated herein or otherwise clearly contradicted by context. Example embodiments are not limited to the described order of the steps.

Furthermore, terms such as “ . . . portion,” “ . . . unit,” “ . . . module,” and “ . . . block” stated in the disclosure may signify a unit to process at least one function or operation and the unit may be embodied by hardware, software, or a combination of hardware and software.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language (e.g., “such as”) provided herein, is intended merely to better illuminate the disclosure and does not pose a limitation on the scope of the disclosure unless otherwise claimed.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hafnium oxide (HfOₓ (1.8≤x≤2.0))-based ferroelectrics having characteristics of maintaining ferroelectricity in the form of an ultrathin film having a thickness of several nanometers may be highly used for semiconductor devices. Hafnium oxide-based ferroelectrics having various polymorphs may have ferroelectricity when having a specific crystal phase. In a hafnium oxide-based ferroelectric thin film, a coercive field Ec needs to vary depending on products. For example, a hafnium oxide-based ferroelectric thin film used for DRAM needs to generally have a low coercive field Ec because a faster operation speed, a smaller operation voltage, and/or higher reliability are desired. In contrast, a hafnium oxide-based ferroelectric thin film used for NAND needs to generally have a higher coercive field Ec for multi-bit driving.

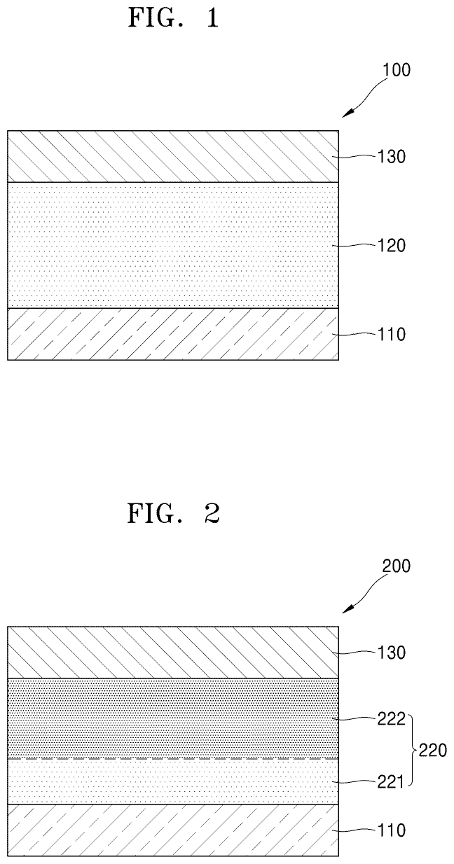

FIG. 1 is a schematic cross-sectional view of a ferroelectric structure 100 according to an example embodiment.

Referring to FIG. 1, the ferroelectric structure 100 may include a substrate 110, a ferroelectric layer 120, and an electrode 130. The substrate 110 may include a semiconductor material. In this case, the ferroelectric structure 100 may be, for example, an electric field effect transistor (FET). The substrate 110 may include, for example, a Group IV semiconductor, such as Si, Ge, SiGe, etc., or a Group III-V semiconductor compound. The substrate 110 may include, for example, oxide semiconductor, nitride semiconductor, oxynitride semiconductor, a two-dimensional (2D) semiconductor material, quantum dots, or organic semiconductor. However, this is only an example. The substrate 110 may further include a dopant. Here, the dopant may include a p-type dopant or an n-type dopant. The p-type dopant may include, for example, a Group III element, such as B, Al, Ga, In, etc., and the n-type dopant may include, for example, Group V element, such as P, As, Sb, etc. The doping concentration of dopant may be, for example, about 10¹⁵/cm³ to about 10²⁰/cm³, but example embodiments are not limited thereto.

The substrate 110 may include a conductive material. In this case, the ferroelectric structure 100 may be, for example, a capacitor. The substrate 110 may include, for example, metal, metal nitride, metal oxide, or a combination thereof. The metal may include, for example, ruthenium (Ru), titanium (Ti), tantalum (Ta), niobium (Nb), iridium (Ir), molybdenum (Mo), tungsten (W), platinum (Pt), etc. The metal nitride may include, for example, titanium nitride (TiN), tantalum nitride (TaN), niobium nitride (NbN), molybdenum nitride (MoN), cobalt nitride (CON), tungsten nitride (WN), etc. The metal oxide may include, for example, platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), or lanthanum strontium cobalt oxide ((La,Sr)CoO₃), etc. The substrate 110 may have a single material layer or a stack structure including a plurality of material layers.

The electrode 130 is provided on top of the substrate 110. The electrode 130 may include a conductive material. The electrode 130 may include, for example, metal, conductive metal nitride, conductive metal oxide, or a combination thereof. The electrode 130 may include, for example, highly doped polysilicon, metal carbide, or a two-dimensional conductive material. The metal carbide may be a metal carbide doped with aluminum or silicon.

The ferroelectric layer 120 is provided between the substrate 110 and the electrode 130. The ferroelectric layer 120 may include a hafnium oxide (HfOₓ (1.8≤x≤2.0))-based ferroelectric. The hafnium oxide-based ferroelectric may have a rhombohedral phase and include samarium (Sm) as a dopant. In the hafnium oxide-based ferroelectric, the rhombohedral phase may be a dominant phase. This means that the proportion of the rhombohedral phase in the hafnium oxide-based ferroelectric is the largest compared with the proportions of other crystal phases (e.g., an orthorhombic phase, etc.). For example, a content of the rhombohedral phase in the hafnium oxide-based ferroelectric may be about 30% to about 80%. However, example embodiments are not limited thereto. For example, the content of the rhombohedral phase in the hafnium oxide-based ferroelectric may be about 50% to about 80%.

The content of Sm in the hafnium oxide-based ferroelectric may be about 1 at % to about 5 at %, but example embodiments are not limited thereto. The hafnium oxide-based ferroelectric may further include at least one of Zr, La, Al, Si, or Y. The ferroelectric layer 120 may have a thickness of about 2 nm or more. For example, the ferroelectric layer 120 may have a thickness of 2 nm to 20 nm. However, example embodiments are not limited thereto.

In the ferroelectric structure 100 according to the present example embodiment, as the ferroelectric layer 120 may include a hafnium oxide-based ferroelectric having a rhombohedral phase and doped with Sm, compared with a hafnium oxide-based ferroelectric that is not doped with Sm, the coercive field Ec may be reduced, and the remnant polarization Pr may be increased.

In the example embodiment described above, a case in which the entire area of the ferroelectric layer 120 is doped with Sm is described. It may be possible that only a partial area of the ferroelectric layer 120 is doped with Sm. FIG. 2 is a schematic cross-sectional view of a ferroelectric structure 200 according to another example embodiment. In the following description, differences from the example embodiment described above are mainly described.

Referring to FIG. 2, the ferroelectric structure 200 may include the substrate 110, a ferroelectric layer 220, and the electrode 130. As the substrate 110 and the electrode 130 are described in detail in the example embodiment described above, descriptions thereof are omitted. The ferroelectric layer 220 is provided between the substrate 110 and the electrode 130. The ferroelectric layer 220 may include a first region 221 provided on the substrate 110 and a second region 222 provided on the first region 221.

The first region 221 may be provided on an upper surface of the substrate 110. The first region 221 may include a hafnium oxide-based ferroelectric having a rhombohedral phase and doped with Sm. In the ferroelectric of the first region 221, the rhombohedral phase may be a dominant phase. The content of the rhombohedral phase in the ferroelectric of the first region 221 may be about 30% to about 80% (e.g., about 50% to about 80%). However, example embodiments are not limited thereto. The content of Sm in the ferroelectric of the first region 221 may be about 1 at % to about 5 at %, but example embodiments are not limited thereto. The ferroelectric of the first region 221 may further include at least one of Zr, La, Al, Si, or Y. The first region 221 may have a thickness of about 3 nm or less. For example, the first region 221 may have a thickness of about 1 nm to about 3 nm, but example embodiments are not limited thereto.

The second region 222 may be provided on an upper surface of the first region 221. The second region 222 may include a hafnium oxide-based ferroelectric that has a rhombohedral phase and is not doped with Sm. The first region 221 may serve as a seed layer for growth of the second region 222. In the second region 222 of the ferroelectric layer 220, the rhombohedral phase may be a dominant phase. The content of the rhombohedral phase in the second region 222 may be about 30% to about 80% (e.g., about 50% to about 80%). However, example embodiments are not limited thereto. The ferroelectric of the second region 222 may further include at least one of Zr, La, Al, Si, or Y. The second region 222 may have a thickness of about 2 nm or more. For example, the second region 222 may have a thickness of about 2 nm to about 20 nm, but example embodiments are not limited thereto.

In the ferroelectric structure 200 according to the present example embodiment, as the ferroelectric layer 220 includes the first region 221 including a hafnium oxide-based ferroelectric having a rhombohedral phase and doped with Sm, and the second region 222 including a hafnium oxide-based ferroelectric having a rhombohedral phase, compared with the hafnium oxide-based ferroelectric that is not doped with Sm, the coercive field Ec may be reduced.

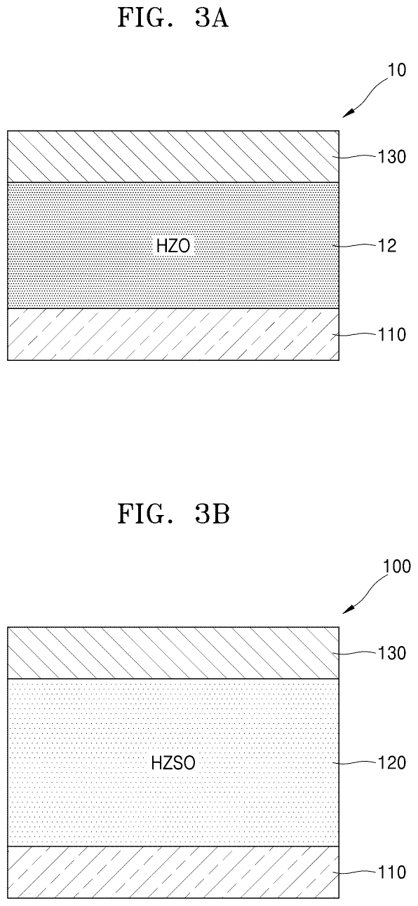

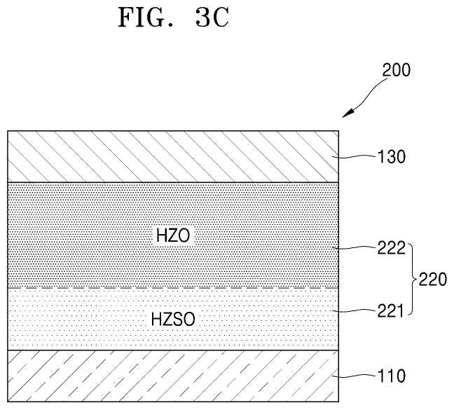

FIGS. 3A to 3C illustrate a ferroelectric structure 10 according to a comparative example, a ferroelectric structure 100 according to one embodiment, and a ferroelectric structure 200 according to another embodiment, respectively, which are used for comparative experiments

FIG. 3A illustrates the ferroelectric structure 10 according to a comparative example. Referring to FIG. 3A, a ferroelectric layer 12 is provided between a substrate 110 and an electrode 130, and the ferroelectric layer 12 may include a hafnium oxide-based ferroelectric. A Hf_{0.5}Zr_{0.5}O₂ (“HZO”) ferroelectric having a rhombohedral phase and having a thickness of 10 nm is used as the hafnium oxide-based ferroelectric.

FIG. 3B illustrates the ferroelectric structure 100 according to the example embodiment illustrated in FIG. 1. Referring to FIG. 3B, the ferroelectric layer 120 is provided between the substrate 110 and the electrode 130, and the ferroelectric layer 120 may include a hafnium oxide-based ferroelectric dope with Sm at about 2 at %. The hafnium oxide-based ferroelectric doped with Sm may have a rhombohedral phase, and a Hf_{0.5}Zr_{0.48}Sm_{0.02}O₂(“HZSO”) ferroelectric having a thickness of about 10 nm is used for the hafnium oxide-based ferroelectric doped with Sm.

FIG. 3C illustrates the ferroelectric structure 200 according to the example embodiment illustrated in FIG. 2. Referring to FIG. 3C, the ferroelectric layer 220 is provided between the substrate 110 and the electrode 130, and the ferroelectric layer 220 may include the first region 221 including a hafnium oxide-based ferroelectric doped with Sm at about 2 at % and the second region 222 including a hafnium oxide-based ferroelectric that is not doped with Sm. A Hf_{0.5}Zr_{0.48}Sm_{0.02}O₂(“HZSO”) ferroelectric having a rhombohedral phase and having a thickness of about 2 nm is used for the hafnium oxide-based ferroelectric doped with Sm in the first region 221, and a Hf0.5Zr_{0.5}O₂ (“HZO”) ferroelectric having a rhombohedral phase and having a thickness of about 8 nm is used for the hafnium oxide-based ferroelectric that is not doped with Sm in the second region 222. In other words, an “HZO/HZSO” ferroelectric is used as the ferroelectric used in the ferroelectric structure 200 according to another embodiment illustrated in FIG. 3C.

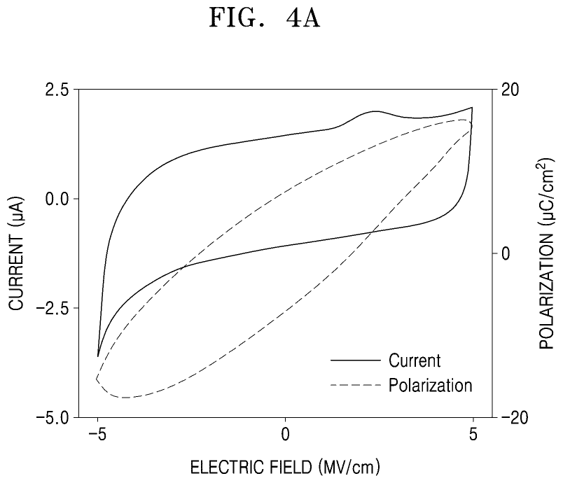

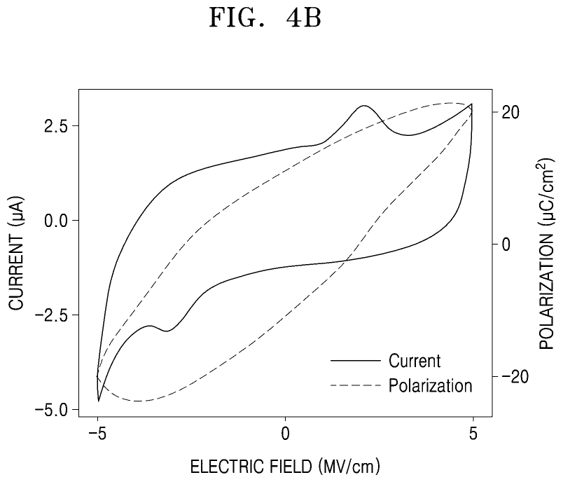

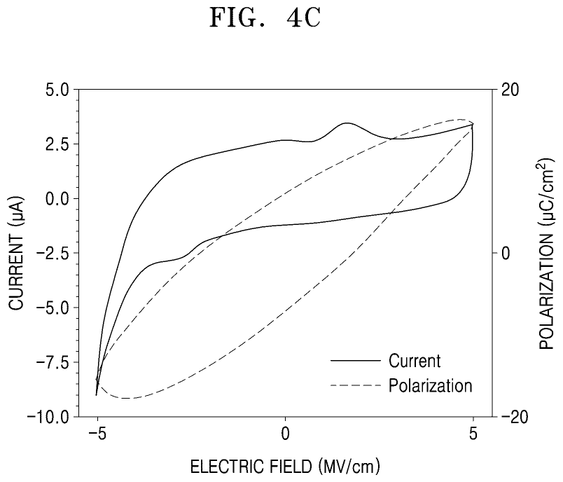

FIGS. 4A to 4C are graphs showing results of measuring current characteristics and polarization characteristics of an “HZO” ferroelectric according to the comparative example illustrated in FIG. 3A, the “HZSO” ferroelectric according to the example embodiment illustrated in FIG. 3B, and the “HZO/H″SO” ferroelectric according to the example embodiment illustrated in FIG. 3C.

FIG. 4A illustrates the current characteristics and the polarization characteristics of the “HZO” ferroelectric illustrated in FIG. 3A. Referring to FIG. 4A, in the “HZO” ferroelectric, at an electric field of 5 MV/cm, the remnant polarization Pr is measured to be about 7.2 μC/cm², and the coercive field Ec is measured to be about 3.1 MV/cm. FIG. 4B illustrates the current characteristics and the polarization characteristics of the “HZSO” ferroelectric illustrated in FIG. 3B. Referring to FIG. 4B, in the “HZSO” ferroelectric, at an electric field of 5 MV/cm, the remnant polarization Pr is measured to be about 11 μC/cm², and the coercive field Ec is measured to be about 2.6 MV/cm. FIG. 4C illustrates the current characteristics and the polarization characteristics of the “HZO/HZSO” ferroelectric illustrated in FIG. 3C. Referring to FIG. 4C, in the “HZSO” ferroelectric, at an electric field of 5 MV/cm, the remnant polarization Pr is measured to be about 7.2 μC/cm², and the coercive field Ec is measured to be about 2.3 MV/cm.

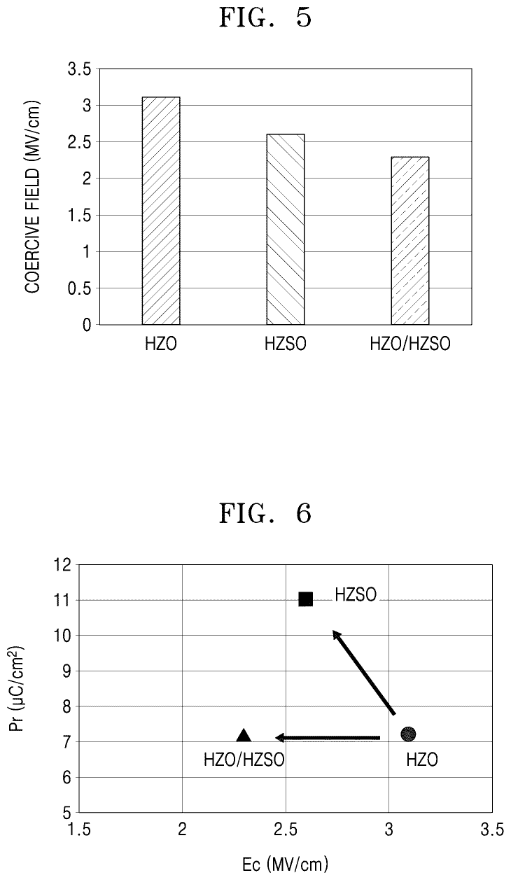

FIG. 5 is a graph showing a comparison of the coercive fields, which are obtained from the measurement results illustrated in FIGS. 4A to 4C, with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C.

Referring to FIG. 5, it may be seen that the coercive field of the “HZSO” ferroelectric according to one example embodiment is reduced by about 16%, compared with the “HZO” ferroelectric according to the comparative example, and that the coercive field of the “HZO/HZSO” ferroelectric according to another example embodiment is reduced by about 26%, compared with the “HZO” ferroelectric according to the comparative example.

FIG. 6 is a graph showing a comparison of the coercive fields Ec and the remnant polarization Pr, which are obtained from the measurement results illustrated in FIGS. 4A to 4C, with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C.

Referring to FIG. 6, it may be seen that the coercive field Ec and the remnant polarization Pr of the “H″SO” ferroelectric according to one example embodiment are reduced by about 16% and about 53%, respectively, compared with the “HZO” ferroelectric according to the comparative example. It may be seen that, compared with the “HZO” ferroelectric according to the comparative example, the coercive field Ec of the “HZO/HZSO” ferroelectric according to another example embodiment is reduced by about 26%, and the remnant polarization Pr is hardly changed.

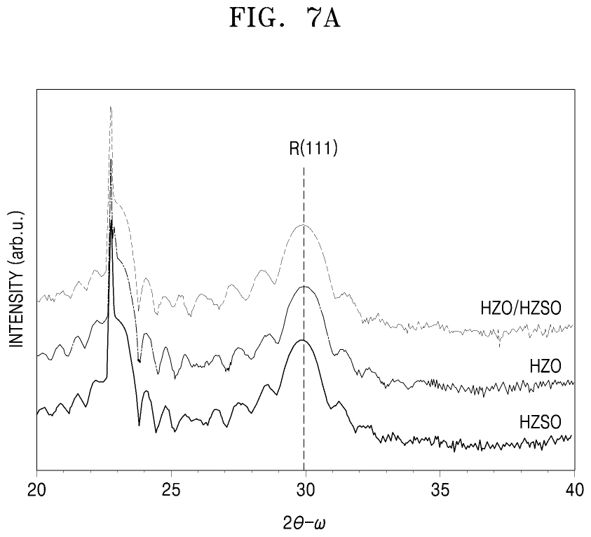

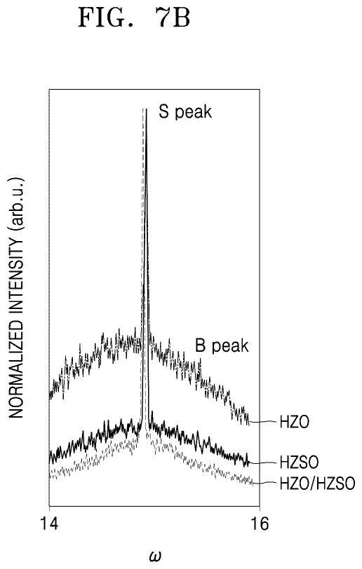

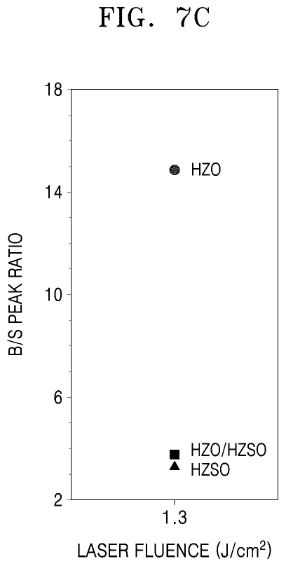

FIG. 7A is a graph showing an X-ray diffraction (XRD) analysis result (a diffraction peak according to a 2θ-ω change) with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C. Referring to FIG. 7A, as an R(111) peak is observed in all of the “HZO” ferroelectric, the “HZSO” ferroelectric, and the “HZO/HZSO” ferroelectric, it may be seen that all the ferroelectrics have a rhombohedral phase.

FIG. 7B is a graph showing an X-ray rocking curve (a diffraction peak according to a ω change) with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C. FIG. 7C is a graph showing quantification of a ratio of a “B” peak to an “S” peak, from the result illustrated in FIG. 7B, with respect to the “HZO” ferroelectric according to the comparative example illustrated in FIG. 3A, the “HZSO” ferroelectric according to the example embodiment illustrated in FIG. 3B, and the “HZO/HZSO” ferroelectric according to the example embodiment illustrated in FIG. 3C

Referring to FIGS. 7B and 7C, it may be seen that, in the “HZSO” ferroelectric doped with Sm and the “HZO/HZSO” ferroelectric doped with Sm, compared with the “HZO” ferroelectric that is not doped with Sm, the “B” peak is reduced so that crystallinity is improved.

As described above, by doping Sm into a hafnium oxide-based ferroelectric having a rhombohedral phase, the coercive field Ec and the remnant polarization Pr may be controlled. Accordingly, by using the ferroelectric structures 100 and 200 according to the example embodiments, a semiconductor device satisfying the coercive field Ec and the remnant polarization Pr desired depending on the application field may be implemented.

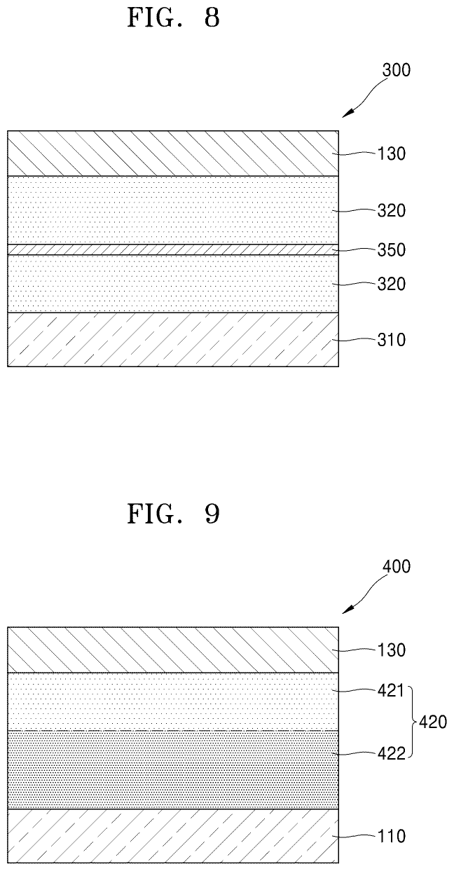

FIG. 8 is a schematic cross-sectional view of a ferroelectric structure 300 according to another example embodiment. In the following description, differences from the example embodiments described above are mainly described.

Referring to FIG. 8, a ferroelectric layer 320 is provided between the substrate 110 and the electrode 130. The ferroelectric layer 320 may include, as described above, the hafnium oxide-based ferroelectric having a rhombohedral phase and doped with Sm. Sm may be doped in the entire area of the ferroelectric layer 320 or in a partial area of the ferroelectric layer 320. At least one interface layer 350 is provided inside the ferroelectric layer 320. The interface layer 350 serves to reinforce ferroelectricity of a ferroelectric layer, and may include, for example, aluminum oxide (AlOₓ) or tantalum oxide (TaOₓ), etc. However, example embodiments are not limited thereto. The interface layer 350 may have a thickness of about 0.2 nm or more, but example embodiments are not limited thereto. FIG. 8 illustrates, as an example, a case in which one interface layer 350 is provided inside the ferroelectric layer 320. However, example embodiments are not limited thereto, and a plurality of interface layers may be provided inside the ferroelectric layer 320.

FIG. 9 is a schematic cross-sectional view of a ferroelectric structure 400 according to another example embodiment.

Referring to FIG. 9, a ferroelectric layer 420 provided between the substrate 110 and the electrode 130 may include a first region 421 and a second region 422. The first region 421 may be provided on a lower surface of the electrode 130. The first region 421 may include a hafnium oxide-based ferroelectric having a rhombohedral phase and doped with Sm. The first region 421 may have a thickness of about 3 nm or less. For example, the first region 421 may have a thickness of about 1 nm to about 3 nm, but example embodiments are not limited thereto. The second region 422 is provided on a lower surface of the first region 421. The second region 422 may include a hafnium oxide-based ferroelectric that has a rhombohedral phase and is not doped with Sm. The second region 422 may have a thickness of about 2 nm or more. For example, the second region 422 may have a thickness of about 2 nm to about 20 nm, but example embodiments are not limited thereto.

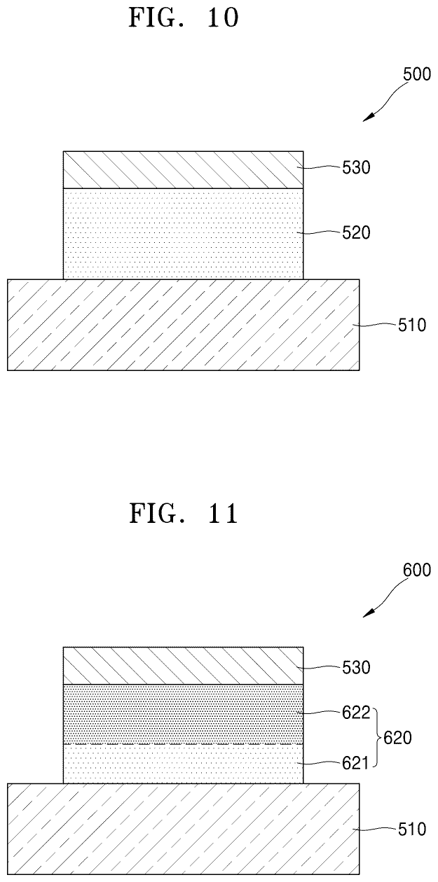

As described above, the ferroelectric structures 100, 200, 300, and 400 may be applied to various semiconductor devices. FIG. 10 is a schematic cross-sectional view of a semiconductor device 500 according to an example embodiment. The semiconductor device 500 illustrated in FIG. 10 may be, for example, a ferroelectric electric field effect transistor (FeFET).

Referring to FIG. 10, the semiconductor device 500 may sequentially include a channel layer 510, a ferroelectric layer 520, and a gate electrode 530. The channel layer 510 may include a semiconductor material. The channel layer 510 may include, for example, a Group IV semiconductor, such as Si, Ge, SiGe, etc., or a Group III-V semiconductor compound. The channel layer 510 may include, for example, oxide semiconductor, nitride semiconductor, oxynitride semiconductor, a 2D semiconductor material, quantum dots, or organic semiconductor. However, this is only an example. The channel layer 510 may further include a dopant. The dopant may include a p-type dopant or an n-type dopant. The p-type dopant may include, for example, a Group III element, such as B, Al, Ga, In, etc., and the n-type dopant may include, for example, a Group V element, such as P, As, Sb, etc. The doping concentration of dopant may be, for example, about 10¹⁵/cm³ to about 10²⁰/cm³, but example embodiments are not limited thereto.

The gate electrode 530 may include a conductive material. The gate electrode 530 may include, for example, metal, metal nitride, metal oxide, or a combination thereof. The metal may include, for example, Ru, Ti, Ta, Nb, Ir, Mo, W, Pt, etc. The metal nitride may include, for example, TiN, TaN, NbN, MON, CON, WN, etc. The metal oxide may include, for example, PtO, IrO₂, RuO₂, SrRuO₃, (Ba,Sr)RuO₃, CaRuO₃, (La,Sr)CoO₃, etc. The gate electrode 530 may include, for example, highly doped polysilicon, metal carbide, or a 2D conductive material. The gate electrode 530 may have a single material layer or a stack structure including a plurality of material layers.

The ferroelectric layer 520 is provided between the channel layer 510 and the gate electrode 530. The ferroelectric layer 520 may include a hafnium oxide-based ferroelectric having a rhombohedral phase and doped with Sm. The content of the rhombohedral phase in the hafnium oxide-based ferroelectric may be about 50% to about 80%, but example embodiments are not limited thereto. The content of Sm in the hafnium oxide-based ferroelectric may be about 1 at % to about 5 at %, but example embodiments are not limited thereto. The hafnium oxide-based ferroelectric may further include at least one of Zr, La, Al, Si, or Y. The ferroelectric layer 520 may have a thickness of about 2 nm or more. For example, the ferroelectric layer 520 may have a thickness of about 2 nm to about 20 nm. However, example embodiments are not limited thereto.

FIG. 11 is a schematic cross-sectional view of a semiconductor device 600 according to another example embodiment. In the following description, differences from the embodiments described above are mainly described.

Referring to FIG. 11, a ferroelectric layer 620 provided between the channel layer 510 and the gate electrode 530 may include a first region 621 provided on the channel layer 510 and a second region 622 provided on the first region 621. The first region 621 may be provided on an upper surface of the channel layer 510. The first region 621 may include a hafnium oxide-based ferroelectric having a rhombohedral phase and doped with Sm. The content of the rhombohedral phase in the ferroelectric of the first region 621 may be about 30% to about 80% (e.g., about 50% to about 80%). The content of Sm in the ferroelectric of the first region 621 may be about 1 at % to about 5 at %. The ferroelectric of the first region 621 may further include at least one of Zr, La, Al, Si, or Y. The first region 621 may have a thickness of about 3 nm or less. For example, the first region 621 may have a thickness of about 1 nm to about 3 nm, but example embodiments are not limited thereto.

The second region 622 may be provided on an upper surface of the first region 621. The second region 622 may include a hafnium oxide-based ferroelectric that has a rhombohedral phase and is not doped with Sm. The content of the rhombohedral phase in the ferroelectric of the second region 622 may be about 30% to about 80% (e.g., about 50% to about 80%). The ferroelectric of the second region 622 may further include at least one of Zr, La, Al, Si, or Y. The second region 622 may have a thickness of about 2 nm or more. For example, the second region 622 may have a thickness of about 2 nm to about 20 nm, but example embodiments are not limited thereto. FIG. 11 illustrates, as an example, a case in which the first region 621 is provided between the channel layer 510 and the second region 622. However, example embodiments are not limited thereto, and the first region 621 may be provided between the gate electrode 530 and the second region 622.

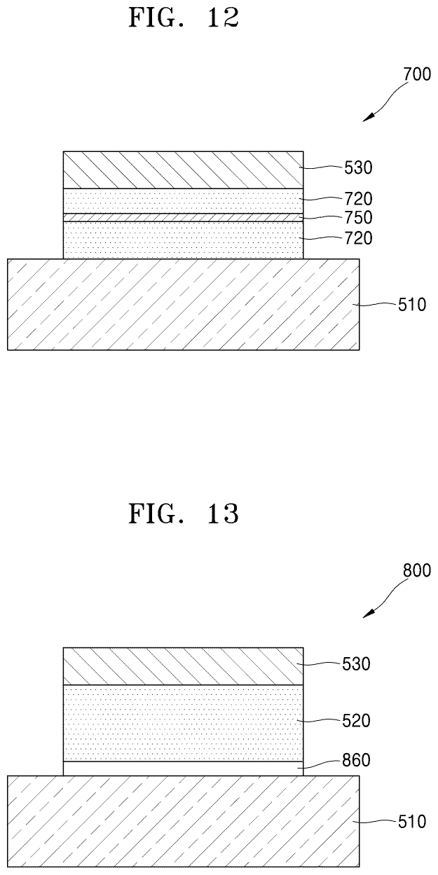

FIG. 12 is a schematic cross-sectional view of a semiconductor device 700 according to another example embodiment.

Referring to FIG. 12, a ferroelectric layer 720 is provided between the channel layer 510 and the gate electrode 530, and at least one interface layer 750 is provided inside ferroelectric layer 720. The ferroelectric layer 720 may include the hafnium oxide-based ferroelectric having a rhombohedral phase and doped with Sm. Sm may be doped in the entire area of the ferroelectric layer 720 or in a partial area of the ferroelectric layer 720. The interface layer 750 serves to reinforce ferroelectricity of the ferroelectric layer 720, and may include, for example, an aluminum oxide (AlOₓ), a tantalum oxide (TaOₓ), etc. The interface layer 750 may have a thickness of about 0.2 nm or more, but example embodiments are not limited thereto.

FIG. 13 is a schematic cross-sectional view of a semiconductor device 800 according to another example embodiment.

Referring to FIG. 13, the ferroelectric layer 520 is provided between the channel layer 510 and the gate electrode 530, and an interface layer 860 is provided between the channel layer 510 and the ferroelectric layer 520. The ferroelectric layer 520 may include the hafnium oxide-based ferroelectric having a rhombohedral phase and doped with Sm. Sm may be doped in the entire area of the ferroelectric layer 520 or in a partial area of the ferroelectric layer 520. The interface layer 860 is deposed on an upper surface of the channel layer 510, and may include, for example, SiOₓ, GeOₓ, SiGeOₓ, SiON, GeON, SiGeOₓN_{y}, etc.

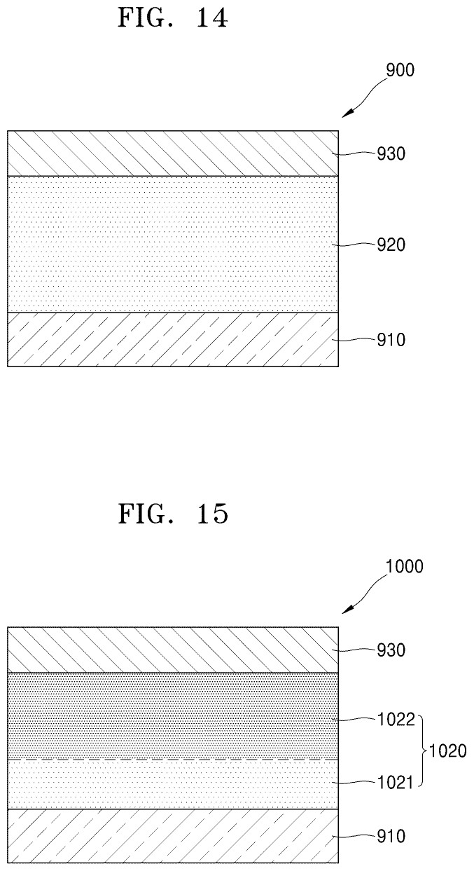

FIG. 14 is a schematic cross-sectional view of a semiconductor device 900 according to another example embodiment. The semiconductor device 900 illustrated in FIG. 14 may be, for example, a capacitor.

Referring to FIG. 14, the semiconductor device 900 may include first and second electrodes 910 and 930 that are apart from each other, and a ferroelectric layer 920 provided between the first electrode 910 and the second electrode 930. The first and second electrodes 910 and 930 may each include a conductive material. The first and second electrodes 910 and 930 may each include, for example, metal, metal nitride, metal oxide, or a combination thereof. The metal may include, for example, Ru, Ti, Ta, Nb, Ir, Mo, W, Pt, etc. The metal nitride may include, for example, TiN, TaN, NbN, MON, CON, WN, etc. The metal oxide may include, for example, PtO, IrO₂, RuO₂, SrRuO₃, (Ba,Sr)RuO₃, CaRuO₃, (La,Sr)CoO₃, etc.

The ferroelectric layer 920 between the first electrode 910 and the second electrode 930 may include a hafnium oxide-based ferroelectric having a rhombohedral phase and doped with Sm. The content of the rhombohedral phase in the hafnium oxide-based ferroelectric may be about 50% to about 80%, but example embodiments are not limited thereto. The content of Sm in the hafnium oxide-based ferroelectric may be about 1 at % to about 5 at %, but example embodiments are not limited thereto. The hafnium oxide-based ferroelectric may further include at least one of Zr, La, Al, Si, or Y. The ferroelectric layer 920 may have a thickness of about 2 nm or more. For example, the ferroelectric layer 920 may have a thickness of about 2 nm to about 20 nm. However, example embodiments are not limited thereto.

Although not illustrated in the drawing, at least one interface layer for improving ferroelectricity may be further provided inside the ferroelectric layer 920, and/or an interface layer including a dielectric material may be further provided between the first electrode 910 and the ferroelectric layer 920.

FIG. 15 is a schematic cross-sectional view of a semiconductor device 1000 according to another example embodiment. In the following description, differences from the example embodiments described above are mainly described.

Referring to FIG. 15, a ferroelectric layer 1020 provided between the first electrode 910 and the second electrode 930 may include a first region 1021 provided on the first electrode 910 and a second region 1022 provided on the first region 1021. The first region 1021 may be provided on an upper surface of the first electrode 910. The first region 1021 may include a hafnium oxide-based ferroelectric having a rhombohedral phase and doped with Sm. The content of the rhombohedral phase in the ferroelectric of the first region 1021 may be about 30% to about 80% (e.g., about 50% to about 80%). The content of Sm in the ferroelectric of the first region 1021 may be about 1 at % to about 5 at %. The ferroelectric of the first region 1021 may further include at least one of Zr, La, Al, Si, or Y. The first region 1021 may have a thickness of about 3 nm or less. For example, the first region 1021 may have a thickness of about 1 nm to about 3 nm, but example embodiments are not limited thereto.

The second region 1022 is provided on an upper surface of the first region 1021. The second region 1022 may include a hafnium oxide-based ferroelectric that has a rhombohedral phase and is not doped with Sm. The content of the rhombohedral phase in the ferroelectric of the second region 1022 may be about 30% to about 80% (e.g., about 50% to about 80%). The ferroelectric of the second region 1022 may further include at least one of Zr, La, Al, Si, or Y. The second region 1022 may have a thickness of about 2 nm or more. For example, the second region 1022 may have a thickness of about 2 nm to about 20 nm, but example embodiments are not limited thereto. FIG. 15 illustrates, as an example, a case in which the first region 1021 is provided between the first electrode 910 and the second region 1022. However, example embodiments are not limited thereto, and the first region 1021 may be provided between the second electrode 930 and the second region 1022.

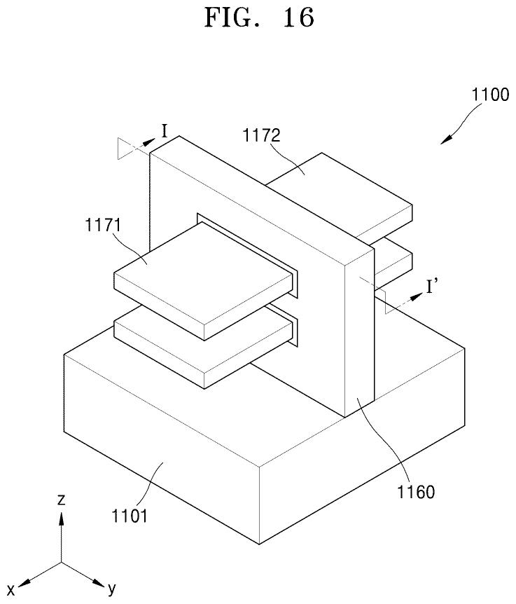

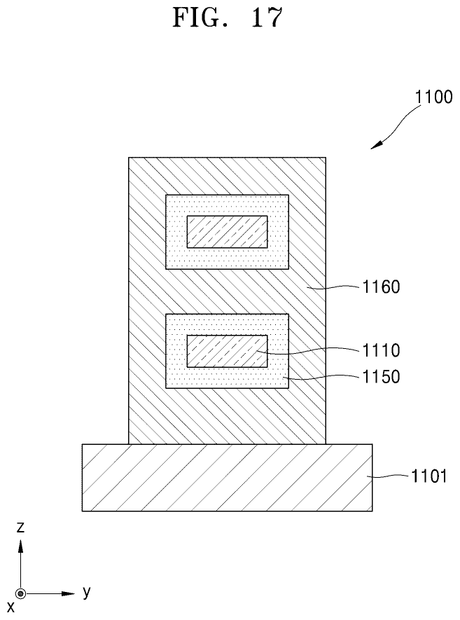

FIG. 16 is a perspective view of a semiconductor device 1100 according to another example embodiment. FIG. 17 is a cross-sectional view of line I-I′ of FIG. 16. The semiconductor device 1100 illustrated in FIG. 16 may be a FeFET of a multi-bridge channel (MBC) structure.

Referring to FIGS. 16 and 17, a plurality of channel layers 1110 are arranged above a substrate 1101 to be apart from the substrate 1101. FIGS. 16 and 17 illustrate, as an example, a case in which two channel layers 1110 are vertically arranged above the substrate 1101. However, this is just an example, and two channel layers 1110 may be horizontally arranged. A source electrode 1171 and a drain electrode 1172 may be provided on both sides of each of the channel layers 1110.

A ferroelectric layer 1150 is stacked to surround the channel layers 1110 in each of the channel layers 1110. The ferroelectric layer 1150 may include, as described above, the hafnium oxide-based ferroelectric having a rhombohedral phase and doped with Sm. Sm may be doped in the entire area of the ferroelectric layer 1150 or in a partial area of the ferroelectric layer 1150. A gate electrode 1160 surround the ferroelectric layer 1150 outside the channel layers 1110. The gate electrode 1160 may surround four sides of each of the channel layers 1110.

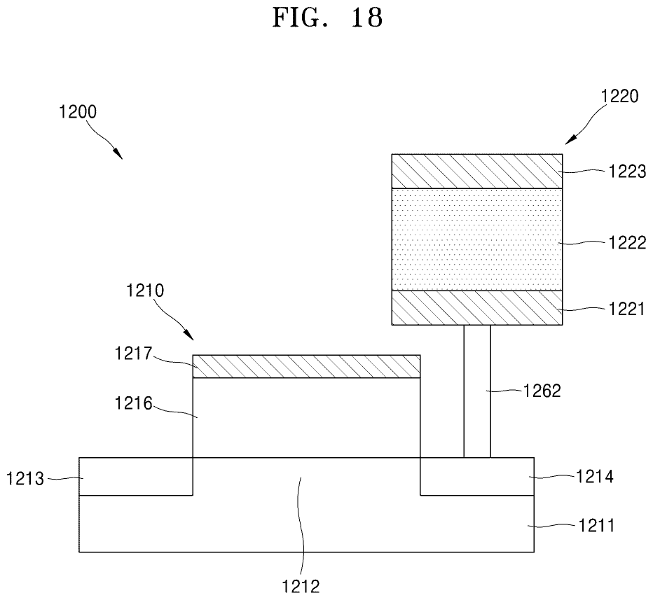

FIG. 18 illustrates a semiconductor device 1200 according to an example embodiment. The semiconductor device illustrated in FIG. 18 may be a DRAM cell having a 1 transistor and 1 capacitor (1T1C) structure.

Referring to FIG. 18, the semiconductor device 1200 may have a structure in which an EFT transistor 1210 and a capacitor 1220 are electrically connected to each other by a contact 1262. The EFT transistor 1210 may include a substrate 1211 including a channel 1212 and a gate electrode 1217 arranged to face the channel 1212. A dielectric layer 1216 may be provided between the substrate 1211 and the gate electrode 1217.

The substrate 1211 may include a semiconductor material. The substrate 1211 may include, for example, a Group IV semiconductor, such as Si, Ge, SiGe, etc., or a Group III-V semiconductor compound. The substrate 1211 may include, for example, oxide semiconductor, nitride semiconductor, oxynitride semiconductor, a 2D semiconductor material, quantum dots, or organic semiconductor. The oxide semiconductor may include, for example, InGaZnO, etc., the 2D semiconductor material may include, for example, transition metal dichalcogenide (TMD) or graphene, and the quantum dots may include colloidal QDs, a nanocrystal structure, etc. However, this is only an example. The substrate 1211 may further include a dopant.

The substrate 1211 may include a source 1213, a drain 1214, and the channel 1212 electrically connected to the source 1213 and the drain 1214. The source 1213 may be electrically connected to or in contact with one side of the channel 1212, and the drain 1214 may be electrically connected to or in contact with the other side of the channel 1212. In other words, the channel 1212 may be defined as a substrate area between the source 1213 and the drain 1214 within the substrate 1211. The channel 1212 may be implemented by a material layer (e.g., a thin film) (not shown) separated from the substrate 1211.

The gate electrode 1217 may be disposed above the substrate 1211 to be apart from the substrate 1211 to face the channel 1212. The gate electrode 1217 may include a conductive material, such as metal, metal nitride, metal carbide, polysilicon, or etc. A gate insulating layer 1216 may be provided between the substrate 1211 and the gate electrode 1217. The gate insulating layer 1216 may include a paraelectric material or a high-k dielectric material.

The capacitor 1220 may include first and second electrodes 1221 and 1223 and a ferroelectric layer 1222 provided between the first and second electrodes 1221 and 1223. The ferroelectric layer 1222 may include, as described above, a hafnium oxide-based ferroelectric having a rhombohedral phase and doped with Sm. Sm may be doped in the entire area of the ferroelectric layer 1222 or in a partial area of the ferroelectric layer 1222. The first electrode 1221 of the capacitor 1220 may be electrically connected to one of the drain 1214 of the EFT transistor 1210 by the contact 1262. The contact 1262 may include an appropriate conductive material, such as, tungsten, copper, aluminum, polysilicon, etc. The arrangement of EFT transistor 1210 and the capacitor 1220 may be modified in various ways. For example, the capacitor 1220 may be arranged above the substrate 1211, and may have a structure embedded in the substrate 1211.

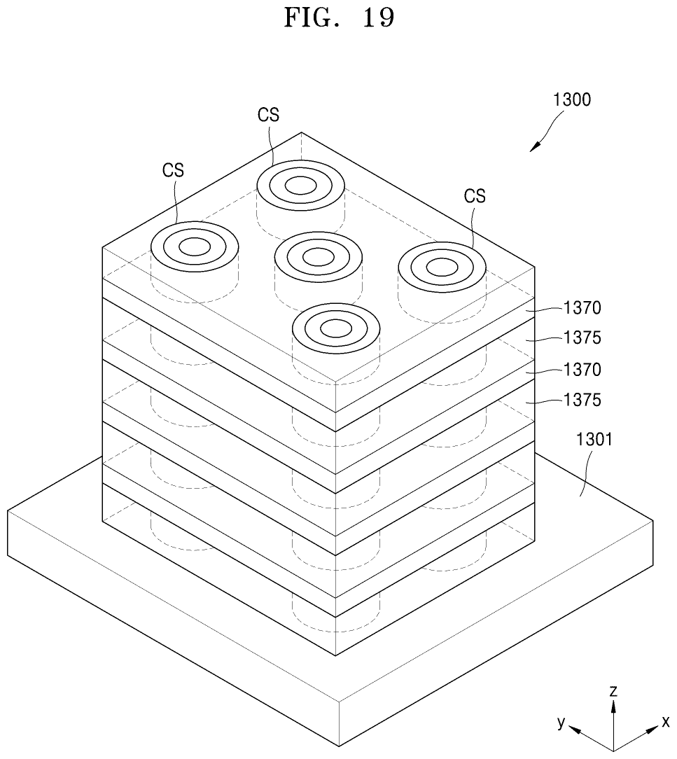

FIG. 19 is a schematic perspective view of a memory device 1300 according to another example embodiment. The memory device 1300 illustrated in FIG. 19 may be a vertical NAND flash.

Referring to FIG. 19, the memory device 1300 may include a plurality of cell arrays CS arranged on a substrate 1301. The cell arrays CS may each extend in a direction (a z-axis direction in FIG. 9) perpendicular to the substrate 1301.

An interlayer insulating layer 1375 and a gate electrode 1370 are alternately stacked above the substrate 1301 in a direction perpendicular to the substrate 1301. Each interlayer insulating layer 1375 and each gate electrode 1370 may be provided above the substrate 1301 in parallel with each other. The substrate 1301 may include various materials. For example, the substrate 1301 may include a single crystal silicon substrate, a compound semiconductor substrate, or a silicon-on-insulator (SOI) substrate, but example embodiments are not limited thereto. Furthermore, the substrate 1301 may further include, for example, an impurity doped area, an electronic component such as a transistor, etc., or a periphery circuit that selects and controls a plurality of memory cells MC for storing data.

The gate electrode 1370 may include, for example, metal, metal nitride, impurity doped silicon, or 2D conductive material, etc. However, this is just an example, and the gate electrode 1370 may include various other materials. A word line may be electrically connected to the gate electrode 1370.

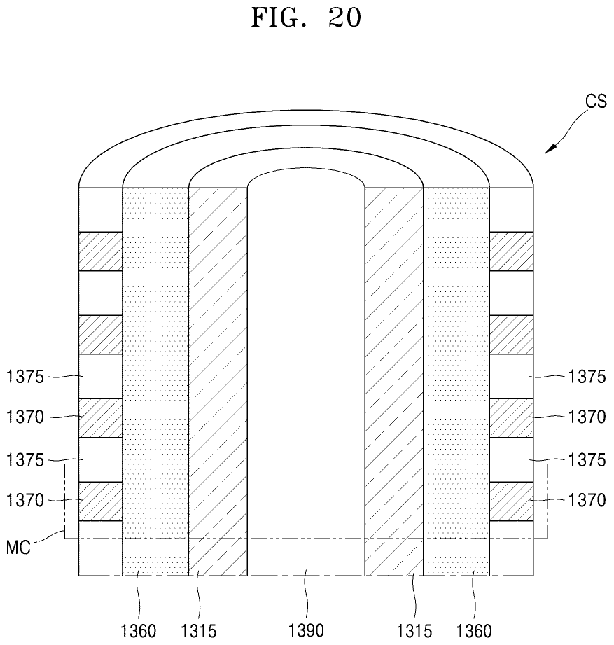

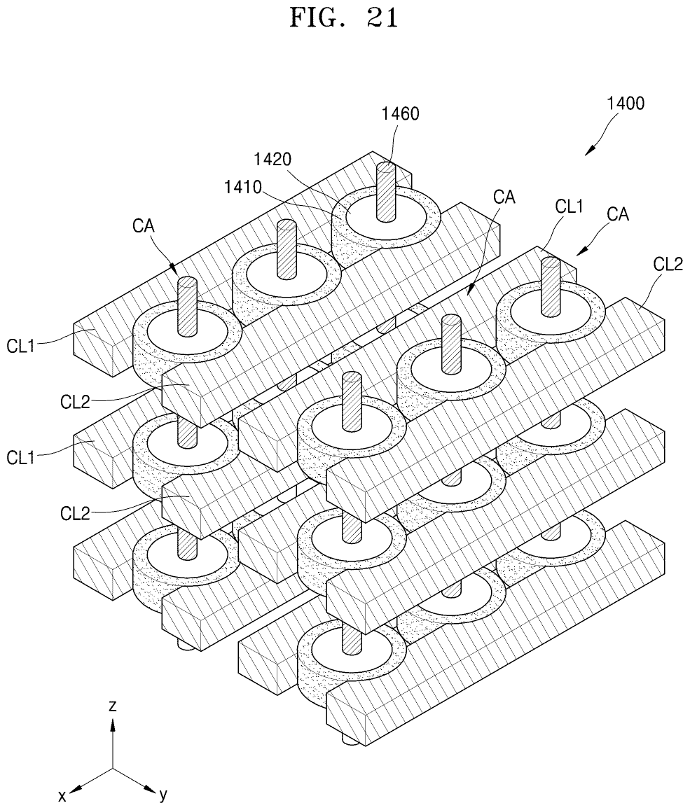

The interlayer insulating layer 1375 may serve as a spacer layer for insulating between the gate electrodes 1370. The interlayer insulating layer 1375 may include, for example, silicon oxide, silicon nitride, etc., but example embodiments are not limited thereto. A channel hole 1390 of FIG. 20 is formed to pass through the interlayer insulating layers 1375 and the gate electrodes 1370 in a direction (the z-axis direction) perpendicular to the substrate 1301. The channel hole 1390 may be formed to have, for example, a circular cross-section. As described below, a ferroelectric layer 1360 and a channel layer 1315 are sequentially provided on an inner wall of the channel hole 1390.

FIG. 20 illustrates a cross-section of the cell arrays CS illustrated in FIG. 19.

Referring to FIG. 20, each of the cell arrays CS may include the memory cells MC stacked in a direction (the z-axis direction) perpendicular to the substrate 1301. The cell arrays CS may include the gate electrodes 1370 stacked in a direction perpendicular to the substrate 1301 to be apart from each other, and the ferroelectric layer 1360 and the channel layer 1315 sequentially provided inside the gate electrodes 1370, which are parallel to the substrate 1301. Each of the ferroelectric layer 1360 and the channel layer 1315 extends perpendicularly to the substrate 1301 and may be shared by the memory cells MC.

The ferroelectric layer 1360 may include, as described above, the hafnium oxide-based ferroelectric having a rhombohedral phase and doped with Sm. Sm may be doped in the entire area of the ferroelectric layer 1360 or a partial area of the ferroelectric layer 1360.

The channel layer 1315 is provided inside the ferroelectric layer 1360. The channel layer 1315 may include a semiconductor material. The channel layer 1315 may include, for example, a Group IV semiconductor, such as Si, Ge, SiGe, etc., or a Group III-V semiconductor compound. The channel layer 1315 may include, for example, oxide semiconductor, nitride semiconductor, oxynitride semiconductor, a 2D semiconductor material, quantum dots, or organic semiconductor. The oxide semiconductor may include, for example, InGaZnO, etc., the 2D semiconductor material may include, for example, TMD or graphene, and the quantum dots may include colloidal QDs, a nanocrystal structure, etc. However, this is only an example. The channel layer 1315 may further include a dopant. The dopant may include a p-type dopant or an n-type dopant. The p-type dopant may include, for example, a Group III element, such as B, Al, Ga, in, etc., and the n-type dopant may include, for example, a Group V element, such as P, As, Sb, etc.

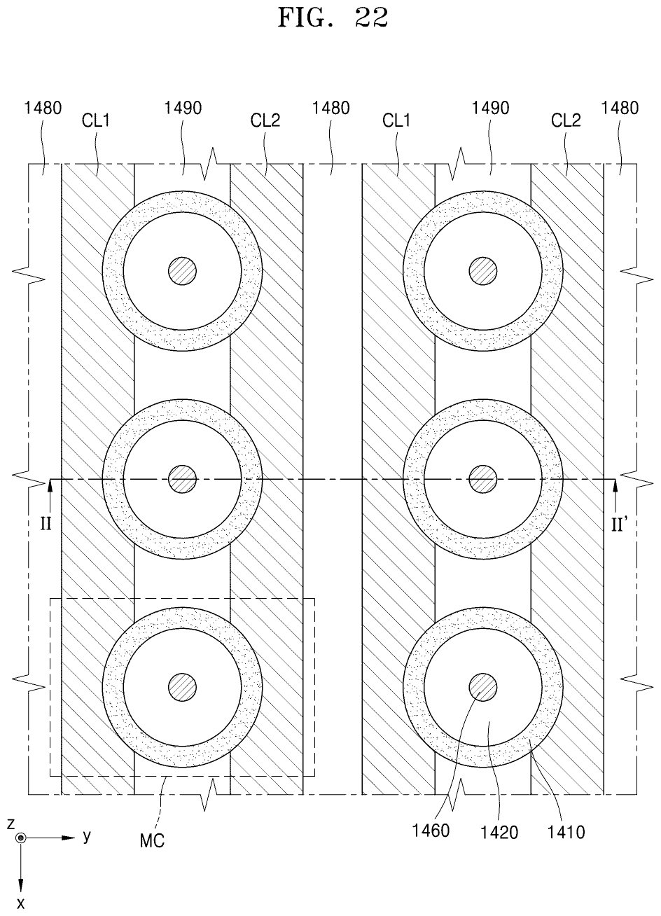

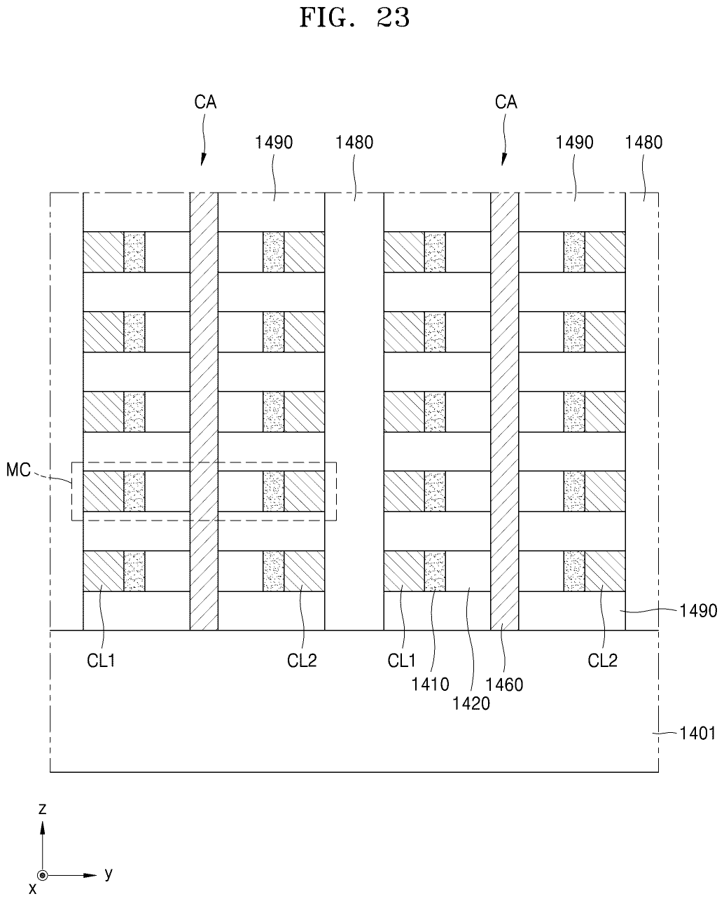

FIG. 21 is a perspective view of a memory device 1400 according to an example embodiment. FIG. 22 is a plan view of the memory device 1400 illustrated in FIG. 21. FIG. 23 is a cross-sectional view of the memory device 1400 taken along line II-II′ of FIG. 22. In the following description, differences from the example embodiments described above are mainly described.

Referring to FIGS. 21 to 23, the memory device 1400 may include a plurality of cell arrays CA two-dimensionally arranged on a substrate 1401. FIG. 21 illustrates, as an example, a case in which the cell arrays CA are arranged in a first direction (an x-axis direction) and a second direction (a y-axis direction) parallel to the substrate 1401.

The cell arrays CA may each extend in a direction (a z-axis direction) perpendicular to the substrate 1401. The cell arrays CA each may include the memory cells MC arranged apart from each other in the direction (the z-axis direction) perpendicular to the substrate 1401. Each memory cell MC may include a FeFET.

A first conductive line CL1 and a second conductive line CL2 are provided on both sides of the memory cells MC, which are arranged apart from each other in the first direction (the x-axis direction) parallel to the substrate 1401. For example, the first and second conductive lines CL1 and CL2 may be a source electrode and a drain electrode, respectively. The first and second conductive lines CL1 and CL2 may be shared by the memory cells MC arranged in the first direction (the x-axis direction). A first insulating material 1480 may be provided between the cell arrays CA arranged apart from each other in the second direction (the y-axis direction) parallel to the substrate 1401. A second insulating material 1490 may be provided between the memory cells MC arranged apart from each other in the direction (the z-axis direction) perpendicular to the substrate 1401. Furthermore, the second insulating material 1490 may fill between the first and second conductive lines CL1 and CL2 while surrounding the memory cells MC.

The substrate 1401 may include various materials. For example, the substrate 1401 may include a single crystal silicon substrate, a compound semiconductor substrate, or an SOI substrate, but example embodiments are not limited thereto. Furthermore, the substrate 1401 may further include, for example, an impurity doped area, an electronic component such as a transistor, etc., or a periphery circuit that selects and controls the memory cells MC for storing data.

Each memory cell MC has a structure in which a gate electrode 1460, a ferroelectric layer 1420, and a channel layer 1410 are sequentially stacked structure in a direction parallel to the substrate 1401. The gate electrode 1460 extends perpendicularly to the substrate 1401 and may be shared by the memory cells MC constituting a corresponding cell array CA. The ferroelectric layer 1420 and the channel layer 1410 may each be formed in a cylindrical shape surrounding the gate electrode 1460.

The gate electrode 1460 may include a conductive material. The gate electrode 1460 may include, for example, metal, metal nitride, metal oxide, polysilicon, etc. As a detailed example, the gate electrode 1460 may include at least one of W, TiN, TaN, WN, NbN, Mo, Ru, Ir, RuO, IrO, or highly doped polysilicon. The gate electrode 1460 may include metal carbide or a 2D conductive material.

The channel layer 1410 may include, for example, a Group IV semiconductor, such as Si, Ge, SiGe, etc., or a Group III-V semiconductor compound. The channel layer 1410 may include, for example, oxide semiconductor, nitride semiconductor, oxynitride semiconductor, a 2D semiconductor material, quantum dots, or organic semiconductor. However, this is just an example, and example embodiments are not limited thereto. The channel layer 1410 may further include a dopant.

The ferroelectric layer 1420 is provided between the gate electrode 1460 and the channel layer 1410. The ferroelectric layer 1420 may include, as described above, the hafnium oxide-based ferroelectric having a rhombohedral phase and doped with Sm. Sm may be doped in the entire area of the ferroelectric layer 1420 or in a partial area of the ferroelectric layer 420.

FIGS. 21 to 23 illustrate a case in which the ferroelectric layer 1420 and the channel layer 1410 sequentially surrounding the gate electrode 1460 are provided in the direction (the z-axis direction) perpendicular to the substrate 1401 to be separated for each memory cell MC. However, example embodiments are not limited thereto, and both the ferroelectric layer 1420 and the channel layer 1410 may be provided in common for the memory cells MC in the direction (the z-axis direction) perpendicular to the substrate 1401. Furthermore, a portion of the ferroelectric layer 1420 and the channel layer 1410 may be provided to be separated in the direction (the z-axis direction) perpendicular to the substrate 1401 for a corresponding memory cell MC.

The semiconductor devices 100, 200, 300, 400, and 600 and the memory device 500 are described above with reference to the drawings that illustrate the example embodiments, and one skilled in the art would appreciate that various modifications, equivalents, and/or alternatives that do not depart from the spirit and technical scope of the disclosure are encompassed in example embodiments of the disclosure.

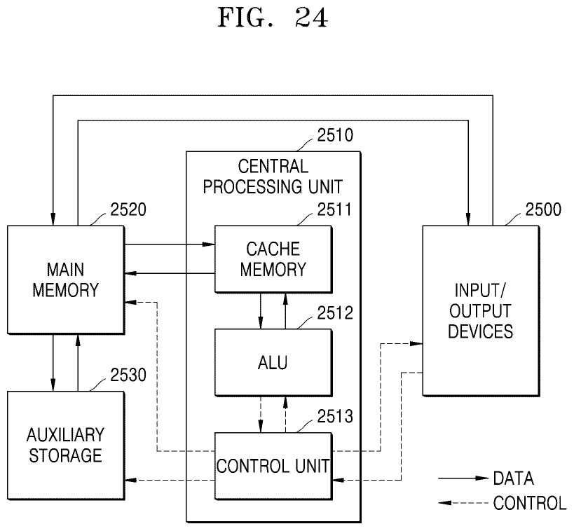

The semiconductor devices 500 to 1200 and the memory devices 1300 and 1400 according to the example embodiments described above may be applied to various electronic devices. FIG. 24 is a conceptual view schematically showing device architecture applicable to an example electronic device.

Referring to FIG. 24, a cache memory 2511, an arithmetic logic unit (ALU) 2512, and a control unit 2513 may constitute a central processing unit (CPU) 2510, and the cache memory 2511 may include a static random access memory (SRAM). Aside from the CPU 2510, a main memory 2520 and an auxiliary storage 2530 may be provided. Furthermore, input/output devices 2500 may be further provided. The main memory 2520 and the auxiliary storage 2530 may each include the memory devices 1300 and 1400 described above. In some cases, the device architecture may be implemented in the form in which computing unit components and memory unit component are adjacent to each other in one chip without distinction of sub-units.

The memory devices 1300 and 1400 described above are implemented as a memory block in the form of a chip and may be used as a neuromorphic computing platform or for establishing a neural network.

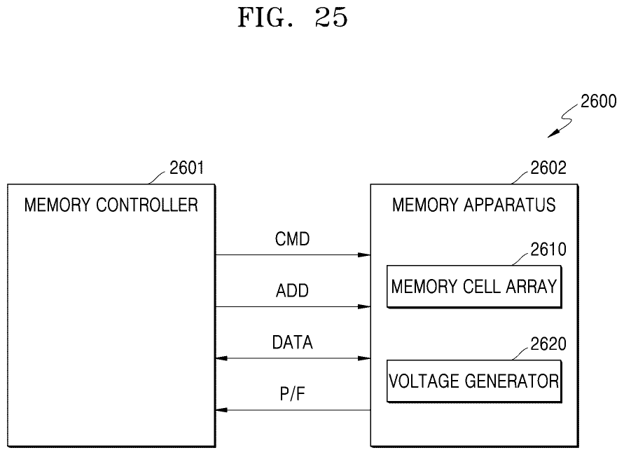

FIG. 25 is a block diagram of a memory system 2600 according to an example embodiment.

Referring to FIG. 25, the memory system 2600 may include a memory controller 2601 and a memory apparatus 2602. The memory controller 2601 performs a control operation on the memory apparatus 2602. For example, the memory controller 2601 provides the memory apparatus 2602 with an address ADD and a command CMD to perform program (or write), read, and/or erase operations with respect to the memory apparatus 2602. Furthermore, data for the program operation and the reading data may be transmitted between the memory controller 2601 and the memory apparatus 2602.

The memory apparatus 2602 may include a memory cell array 2610 and a voltage generator 2620. The memory cell array 2610 may include a plurality of memory cells, and the memory devices 1300 and 1400 described above.

The memory controller 2601 may include a processing circuitry such as hardware including a logic circuit, a hardware/software combination such as processor execution software, or a combination thereof. For example, the processing circuitry may include, in detail, a CPU, an ALU, a digital signal processor, a microcomputer, a field programmable gate array (FPGA), a system-on-chip (SoC), a programmable logic unit, a microprocessor, an application-specific integrated circuit (ASIC), etc., but example embodiments are not limited thereto. The memory controller 2601 may be configured to operate, in response to a request from a host (not shown), access the memory apparatus 2602, and control the control operation (e.g., write/read operation) disclosed above, thereby converting the memory controller 2601 into a special purpose controller. The memory controller 2601 may generate an address ADD and a command CMD to perform program/read/erase operations on the memory cell array 2610. Furthermore, in response to the command CMD from the memory controller 2601, the voltage generator 2620 (e.g., a power circuit) may generate a voltage control signal to control a voltage level of a word line for data programming or data reading/in the memory cell array 2610.

Furthermore, the memory controller 2601 may perform an operation of determining data read out from the memory apparatus 2602. For example, the number of on-cells and/or off-cells may be determined from the data read out from the memory cell. The memory apparatus 2602 may provide a pass/fail signal P/F to the memory controller 2601 according to a reading data reading result. The memory controller 2601 may control write and read operations of the memory cell array 2610 with reference to the pass/fail signal P/F.

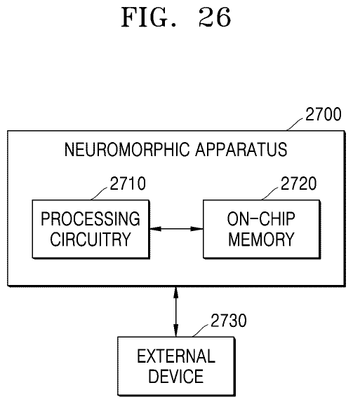

FIG. 26 is a block diagram of a neuromorphic apparatus 2700 according to an example embodiment and an external device 2730 connected thereto.

Referring to FIG. 26, the neuromorphic apparatus 2700 may include a processing circuitry 2710 and/or an on-chip memory 2720. The neuromorphic apparatus 2700 may include the memory devices 1300 and 1400 described above.

In some example embodiments, the processing circuitry 2710 may be configured to control a function to drive the neuromorphic apparatus 2700. For example, the processing circuitry 2710 may be configured to control the neuromorphic apparatus 2700 by executing a program stored in the on-chip memory 2720. In some example embodiments, the processing circuitry 2710 may include hardware such as a logic circuit, a hardware/software combination such as a processor executing software, or a combination thereof. For example, the processor may include a CPU, a graphics processing device (GPU), an application processor (AP) included in the neuromorphic apparatus 2700, an ALU, a digital signal processor, a microcomputer, an FPGA, an SoC, a programmable logic unit, a microprocessor, an ASIC, etc., but example embodiments are not limited thereto. In some example embodiments, the processing circuitry 2710 may be configured to execute read/write various pieces of data with respect to the external device 2730, and/or operate the neuromorphic apparatus 2700 using the read/written data. In some example embodiments, the external device 2730 may include an external memory and/or sensor array including an image sensor (e.g., a CMOS image sensor circuit).

In some example embodiments, the neuromorphic apparatus 2700 of FIG. 26 may be applied to machine learning systems. Such machine learning systems may utilize various artificial neural network organizational and processing models, such as convolutional neural networks (CNN), de-convolutional neural networks, recurrent neural networks (RNN) optionally including long short-term memory (LSTM) units and/or gated recurrent units (GRU), stacked neural networks (SNN), state-space dynamic neural networks (SSDNN), deep belief networks (DBN), generative adversarial networks (GANs), and/or restricted Boltzmann machines (RBM).

Alternatively or additionally, such machine learning systems may include other forms of machine learning models, such as, for example, linear and/or logistic regression, statistical clustering, Bayesian classification, decision trees, dimensionality reduction such as principal component analysis, and expert systems; and/or combinations thereof, including ensembles such as random forests. Such machine learning models may be used to provide various services and/or applications, for example, an image classify service, a user authentication service based on bio-information or biometric data, an advanced driver assistance system (ADAS) service, a voice assistant service, an automatic speech recognition (ASR) service, or the like, and may be executed by other electronic devices.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that the ferroelectric structure, and a semiconductor device and a memory device both using the ferroelectric structure, described herein should be considered in a descriptive sense only and not for purposes of limitation. Descriptions of features or aspects within each example embodiment should typically be considered as available for other similar features or aspects in other example embodiments. While some example embodiments have been described with reference to the figures, it will be understood by those of ordinary skill in the art that various changes in form and details may be made therein without departing from the spirit and scope as defined by the following claims.

What is claimed is:

1. A ferroelectric structure comprising:
a substrate:
a ferroelectric layer on the substrate, the ferroelectric layer including a hafnium oxide-based ferroelectric, the hafnium oxide-based ferroelectric having a rhombohedral phase and doped with samarium (Sm); and
an electrode on the ferroelectric layer.

2. The ferroelectric layer of claim 1, wherein a content of the rhombohedral phase in the ferroelectric layer is 30% to 80%.

3. The ferroelectric layer of claim 1, wherein Sm is doped in an entire area of the ferroelectric layer.

4. The ferroelectric layer of claim 3, wherein a content of Sm in the ferroelectric layer is 1 at % to 5 at %.

5. The ferroelectric layer of claim 1, wherein the ferroelectric layer comprises a first region and a second region, the first region including a hafnium oxide-based ferroelectric doped with Sm, the second region including a hafnium oxide-based ferroelectric undoped with Sm.

6. The ferroelectric layer of claim 1, wherein the hafnium oxide-based ferroelectric further includes at least one of Zr, La, Al, Si, or Y.

7. The ferroelectric layer of claim 1, wherein the ferroelectric structure further comprises at least one interface layer inside the ferroelectric layer.

8. The ferroelectric layer of claim 1, wherein the substrate includes a semiconductor material.

9. The ferroelectric layer of claim 1, wherein the substrate includes a conductive material.

10. A semiconductor device comprising:
a channel layer including a semiconductor material;
a ferroelectric layer on the channel layer, the including a hafnium oxide-based ferroelectric having a rhombohedral phase and doped with samarium (Sm); and
a gate electrode on the ferroelectric layer.

11. The semiconductor device of claim 10, wherein Sm is doped in an entire area of the ferroelectric layer.

12. The semiconductor device of claim 10, wherein the ferroelectric layer comprises a first region and a second region, the first region including a hafnium oxide-based ferroelectric doped with Sm, the second region including a hafnium oxide-based ferroelectric undoped with Sm.

13. The semiconductor device of claim 10, wherein the hafnium oxide-based ferroelectric further includes at least one of Zr, La, Al, Si, or Y.

14. The semiconductor device of claim 10, wherein the semiconductor device further comprises at least one interface layer inside the ferroelectric layer.

15. A memory device comprising:
a plurality of memory cells arranged perpendicular to a substrate,
wherein each of the plurality of memory cells comprises
a channel layer,
a ferroelectric layer on the channel layer, the ferroelectric layer including a hafnium oxide-based ferroelectric having a rhombohedral phase and doped with samarium (Sm), and
a gate electrode on the ferroelectric layer.

16. The memory device of claim 15, wherein the channel layer extends perpendicularly to the substrate.

17. The memory device of claim 15, wherein the gate electrode extends perpendicularly to the substrate.

18. The memory device of claim 15, wherein Sm is doped in an entire area of the ferroelectric layer.

19. The memory device of claim 15, wherein the ferroelectric layer comprises a first region and a second region, the first region including a hafnium oxide-based ferroelectric doped with Sm, the second region including a hafnium oxide-based ferroelectric undoped with Sm.

20. The memory device of claim 15, wherein the hafnium oxide-based ferroelectric further includes at least one of Zr, La, Al, Si, or Y.
